(19) United States
(12) Patent Application Publication
(10) Pub. No.: US 2015/0123663 A1
(43) Pub. Date: May 7, 2015

(54) INTEGRATED ELECTRONICS MODULE WITH COOLING STRUCTURE

(71) Applicant: KONINKLIJKE PHILIPS N.V., EINDHOVEN (NL)

(72) Inventor: Ari Juhani Brusila, Eindhoven (NL)

(21) Appl. No.: 14/396,098

(22) PCT Filed: Apr. 11, 2013
(86) PCT No.: PCT/IB2013/052876

§ 371 Date: Oct. 22, 2014

Related U.S. Application Data
(60) Provisional application No. 61/636,933, filed on Apr. 23, 2012.

(51) Int. Cl. G01R 33/34

(52) U.S. Cl. CPC G01R 33/3403
USPC 324/322

(57) ABSTRACT

An integrated electronics module comprising a substrate with electronics components mounted on a mount-surface of the substrate. A heat-conducting layer is disposed on a cooling-surface of the substrate. The cooling-surface and the mount-surface are on opposite sides of the substrate. A fluid-cooling structure of non-magnetic material and a fluid conduit is mounted in thermal contact with the heat-conducting layer.

### FIELD OF THE INVENTION

The invention pertains to an integrated electronics module with a cooling structure and a substrate which carries electronics components.

### BACKGROUND OF THE INVENTION

Such an integrated electronics module is known form the U.S.-patent U.S. Pat. No. 7,397,665. The known integrated electronics module is formed as a heat-exchanging device with an integral electronics board. This integral electronics board includes a printed-circuit board and an opposite board separated from the printed circuit board. The electronics components are mounted on the printed-circuit board. The space between the printed circuit board and the opposite board forms a reservoir. On top of the electronics components a body of fluid conduits is mounted that is in fluid correspondence with the reservoir. A cooling agent, notably fresh air is entered into the conduits and carried-off through the reservoir between the printed-circuit board and the opposite board.

### SUMMARY OF THE INVENTION

An object of the invention is to provide an integrated electronics module that is compatible with a magnetic resonance environment and that can be manufactured from simple components.

This object is achieved by the integrated electronics module of the invention comprising
a substrate,
electronics components mounted on a mount-surface of the substrate,
a heat-conducting layer disposed on a cooling-surface of the substrate, the cooling-surface and the mount-surface being on opposite sides of the substrate,
a fluid-cooling structure of non-magnetic material and having a fluid conduit mounted in thermal contact with the heat-conducting layer.

The heat-conducting layer with the fluid-cooling structure achieve very good heat-exchange from the electronics components to outside of the integrated electronics module. The heat generated by the electronics components when in operation is transferred through the substrate to the heat-conducting layer. The heat-conducting layer may be a copper or aluminium layer. A copper heat-conducting layer provides a very even spatial temperature distribution due to its higher thermal conductivity. A cooling fluid carries-off the heat externally out of the integrated electronics module. In practice distilled water is found to be a good coolant. The heat-conducting layer allows a standard substrate to be employed, such as a printed circuit board (PCB) or an electrically insulating substrate with electrical connections between the electronics components. This substrate is thin and has a low thermal resistance, so that there is good heat exchange between the electronics components on the mount-surface of the substrate and to the heat-conducting layer on the cooling surface opposite. Typical values for the thermal resistance are for the material of the substrate are for CCAF-01: 1° C./W, or for CCAF-06: 0.4° C./W. Because the fluid-cooling structure is made of non-magnetic material, the integrated electronics module does not influence the operation of an magnetic resonance examination system. It is noted that there are various levels of MRI compatibility. If electronics is applied to parts (like an MRI RF receiver coil) which are inside or very close to imaging volume then the MRI compatibility needs to be near perfect. For the present invention MRI compatibility should be to a degree that some control electronics can be used in the patient table that is still in full magnetic field and affected by the magnetic resonance examination system's gradient and RF fields. For such level of MRI compatibility the distance to imaging volume of the magnetic resonance examination system would be typically one (1) meter or more.

The integrated electronics module of the invention enables to arrange the control electronics close to systems components that are controlled. For example in an MR image guided high-intensity focused ultrasound therapy, system driver amplifiers can be mounted close to a transducer for generating a focused high-intensity ultrasound beam. Also the electronics for controlling electric motors can be provided close to the motors. There are available mechanical positioners with special non-magnetic motors used to rotate (e.g. five) long screws that then control a mechanical positioner/robot. The ultrasound transmitting transducer of a high-intensity focused ultrasound therapy (HIFU) system is fixed to this positioner. The motors can then be used to move the transducer to requested position and angle in five degrees of freedom. Conventional mechanical positioners are known per se form the international applications WO2008/026134 and WO2011/036607. Mechanical positioners for endorectal or transurethral HIFU prostate application would have more simple motor system with only rotating stick—possibly also second motor for moving transducer stick “in/out”.

These and other aspects of the invention will be further elaborated with reference to the embodiments defined in the dependent Claims.

In a preferred embodiment of the integrated electronics module the fluid-conduit is arranged to be contiguous to the heat-conducting layer. This provides excellent thermal contact between the heat-conducting layer and the cooling-structure, notably with a coolant in the fluid conduit so that very efficient heat exchange achieved. This achieves optimum heat exchange between the heat-conducting layer and the cooling fluid in the fluid-conduit. A fluid-tight sealing, for example in the form of an O-ring seal is provided between the fluid-conduit and the heat-conducting layer, so that fluid cannot leak out where the fluid-conduit meets the heat-conducting layer.

In a further embodiment of the invention, the fluid conduit is distributed over the area of the cooling surface. The fluid conduit is formed as a e.g. single, groove from an input liquid connector to an output liquid connector.

In a further embodiment of the invention, a plurality of fluid conduits are provided in the fluid-cooling structure. The heat transfer capacity increases when contact area between heat conducting layer and cooling fluid is maximized amount of fluid flow is maximized. Also several grooves may be formed.

In another preferred embodiment of the invention, the fluid conduit is contiguous to the heat-conducting layer.

These and other aspects of the invention will be elucidated with reference to the embodiments described hereinafter and with reference to the accompanying drawing wherein

### BRIEF DESCRIPTION OF THE DRAWINGS

FIG. 1 shows a schematic side view of the integrated electronics module of the invention.

### DETAILED DESCRIPTION OF THE EMBODIMENTS

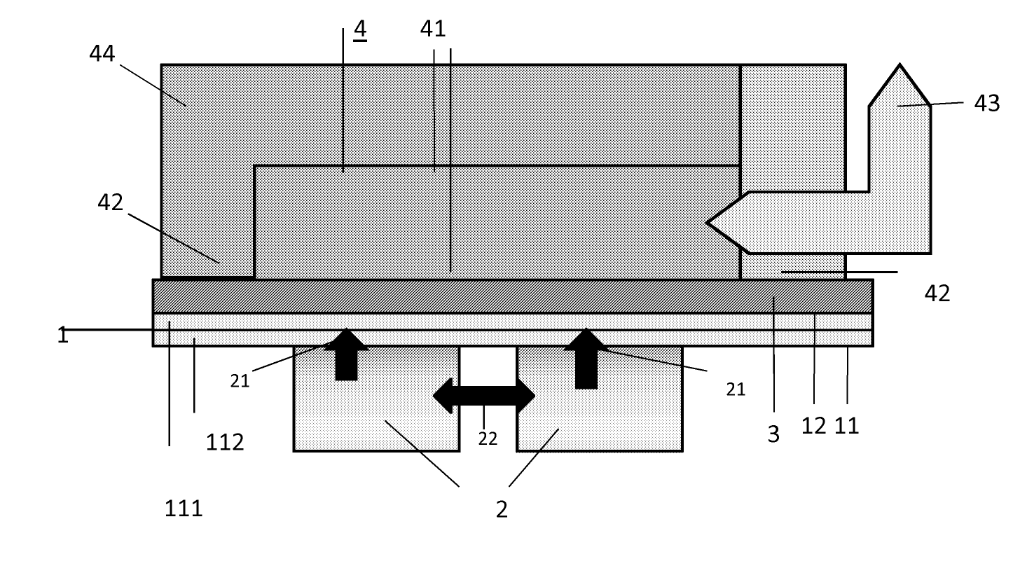

FIG. 1 shows a schematic side view of the integrated electronics module of the invention. On the mount-surface 11 of the substrate 1 several electronics components are mounted. The substrate may be a printed circuit board (PCB) or an electrically insulating layer. The electronics are electrically connected by way of electrical connections 21 to conducting traces 112 on the PCB-surface 111. The PCBs of this kind are typically only single layer boards to maximize heat conductivity and therefore connections are only on component side of PCB. In the event that the electrically insulating layer is used as the substrate, electrical connections 22 may be provided directly between the electronics components. The connections between the electronics components or the electrical connections provided within the PCB establish the electric circuit that defines the functionality of the integrated electronics module. These insulated metal substrate PCBs allow basically only surface mounted components to be assembled (not through-hole (vias) components). As these types of PCB have only one layer, the connection relatively simple circuit layout are preferred as possible otherwise routing of signals may be difficult. Therefore this kind of PCBs typically only have the components that dissipate much power, like amplifiers, regulators', power LEDs or power resistors. The electronics components 2 are mounted to the mount-surface 11 of the substrate. The surface of the substrate opposite the mount-surface is termed the cooling-surface 12.

When in operation, the electronics components will generate heat. The heat-conducting layer 3 is disposed on the cooling-surface 12 as a continuous layer that has high thermal conductivity. For example the heat-conducting layer may be a continuous Cu-layer. The heat-conducting layer provides good heat-exchange between the substrate and the fluid-cooling structure 4. Thus the fluid cooling structure can carry-off the heat generated by the electronics components so that overheating of the integrated electronics module of the invention is avoided. Suitable materials for the heat conducting layer 3 are copper (Thermal conductivity 385 W/m K), or Aluminium (205 W/m K). The heat conductivity of aluminium is often good enough and by using aluminium one can design lighter weight structures.

The fluid-cooling structure includes several fluid conduits 41 through which a cooling fluid is passed. The larger the contact area with cooling fluid and the larger flow the more power could be dissipated and cooled down. For example the dissipated power will be in the range of 50-500 W. This kind of power levels could be air cooled in normal conditions but not in MRI environment where fans do not operate and bringing enough cooling air from longer distance is difficult and not practical. A fluid input/output 43 is provided in fluid correspondence to the fluid conduits to insert cool fluid into the fluid conduits and carry-off heated fluid. Good thermal contact is notably established when one of the fluid conduits is contiguous to the heat-conducting layer 3. The fluid conduit is formed as a e.g. single, groove from the input liquid connector to the output liquid connector. Also several grooves may be formed. These grooves can be simply machined in a plastic block. A fluid-tight sealing 42, here in the form of a ring around the fluid-cooling structure at its interface with the heat-conducting layer is provided to form a fluid-tight barrier which prevents the fluid leaking out of the fluid conduits. For example the O-ring is made of Viton, which is MR compatible.

The fluid-conduits 41 are accommodated in a housing 44. Both the fluid-conduits and the housing are made of a non-magnetic, electrically non-conductive and inexpensive material like plastic. The conduits for cooling liquid are for example arranged only in single layer. There is simply a groove in the bottom of plastic cooling block for the liquid to flow. The fluid-cooling structure does not generate signals in the RF frequency range in response to RF fields and does not generate eddy currents in response to gradient magnetic field pulses. Preferably, the heat-conducting layer is a thin Cu or Al layer.

The invention proposes a cooling system that is MR compatible to a degree that it can be used in MR patient table during MR imaging but not in the immediate vicinity of imaging volume. Notably, the MR compatibility requirement of is not for example as strict as required for MR receiving coils. The MR compatibility of proposed invention is improved if thickness of copper layer is minimized. Slitting of copper layer to several entities reduces the eddy-current effect. The need for slitting to avoid eddy currents is determined by the distance to MR imaging volume.

1. An integrated electronics module comprising
a substrate,
electronics components mounted on a mount-surface of the substrate,
a heat-conducting layer disposed on a cooling-surface of the substrate, the cooling-surface and the mount-surface being on opposite sides of the substrate,
a fluid-cooling structure of non-magnetic material and having a fluid conduit mounted in thermal contact with the heat-conducting layer which is formed as a slotted copper layer.

2. An integrated electronics module as claimed in claim 1, wherein
the fluid conduit is contiguous to the heat-conducting layer and
a fluid-tight sealing is provided contiguous to the fluid conduit outer circumference and to the heat-conducting surface.

3. An integrated electronics module as claimed in claim 1, wherein the fluid conduit is distributed over the area of the cooling surface.

4. An integrated electronics module as claimed in claim 1, wherein the fluid-cooling structure includes a plurality of fluid conduits.
